(19) United States
(12) Patent Application Publication
(10) Pub. No.: US 2022/0137273 A1
(43) Pub. Date: May 5, 2022

(54) COLOR FILTER UNIT AND METHOD OF MANUFACTURING THE SAME

(71) Applicant: Samsung Display Co., Ltd., Yongin-si (KR)

(72) Inventors: Kangsoo HAN, Yongin-si (KR); Sangyeon HWANG, Yongin-si (KR); Songee LEE, Yongin-si (KR); Yooseok JANG, Yongin-si (KR)

(21) Appl. No.: 17/445,476

(22) Filed: Aug. 19, 2021

(30) Foreign Application Priority Data
Nov. 5, 2020 (KR) 10-2020-0147093

(51) Int. Cl. G02B 5/22; H01L 27/32; G02B 5/20

(52) U.S. Cl. CPC G02B 5/22; G02B 5/207; H01L 27/322

(57) ABSTRACT

A color filter unit includes an upper substrate, a color filter layer on a lower surface of the upper substrate, and a quantum dot layer on a lower surface of the color filter layer and including a quantum dot layer material and an arrangement assistant defining a space in which the quantum dot layer material is arranged.

### CROSS-REFERENCE TO RELATED APPLICATION

This application claims priority to and the benefit of Korean Patent Application No. 10-2020-0147093, filed on Nov. 5, 2020, in the Korean Intellectual Property Office, the entire content of which is incorporated by reference herein.

### BACKGROUND

### 1. Field

One or more embodiments relate to a color filter unit and a method of manufacturing the same, and more particularly, to a color filter unit including a quantum dot layer and a method of manufacturing the same.

### 2. Description of Related Art

Display apparatuses may visually display data. A display apparatus may be used as a display unit of a small product such as a mobile phone or may be used as a display unit of a large product such as a television.

A display apparatus may include a plurality of pixels that receive an electrical signal to emit light to display an image to the outside. Each pixel may include a light emitting diode and may include, for example, an organic light emitting diode as a light emitting diode in the case of an organic light emitting display apparatus. Generally, in an organic light emitting display apparatus, a thin film transistor and an organic light emitting diode may be formed on (or over) a substrate, and the organic light emitting diode may itself emit light.

Recently, as the use of display apparatuses has diversified, various attempts have been made to improve the quality of display apparatuses. Particularly, as the high resolution of display apparatuses has progressed, research has been actively conducted to improve the color reproducibility of pixels of display apparatuses.

### SUMMARY

However, in a color filter unit and a method of manufacturing the same according to the related art, there is a problem in that the display quality thereof is degraded because a quantum dot layer is not uniformly formed.

In order to solve various problems including the above problems, aspects of one or more embodiments of the present disclosure are directed toward a color filter unit including a quantum dot layer with improved uniformity and a method of manufacturing the same. However, these problems are merely examples and the scope of the disclosure is not limited thereto.

Additional aspects will be set forth in part in the description which follows and, in part, will be apparent from the description, or may be learned by practice of the presented embodiments.

According to one or more embodiments, a color filter unit includes an upper substrate, a color filter layer on a lower surface of the upper substrate, and a quantum dot layer on a lower surface of the color filter layer and including a quantum dot layer material and an arrangement assistant defining a space in which the quantum dot layer material is arranged.

According to one or more embodiments, the arrangement assistant may include a porous layer including a plurality of spaces connected to each other.

According to one or more embodiments, the quantum dot layer material may fill the plurality of spaces.

According to one or more embodiments, the arrangement assistant may include a plurality of spheres.

According to one or more embodiments, the space defined by the arrangement assistant is a space between the plurality of spheres and the quantum dot layer material may fill the space between the plurality of spheres.

According to one or more embodiments, the plurality of spheres may be hollow.

According to one or more embodiments, at least one hollow interior of the plurality of hollow spheres may be filled with air.

According to one or more embodiments, the quantum dot layer material may fill at least one hollow interior of the hollow spheres.

According to one or more embodiments, the arrangement assistant may include first to third linear portions respectively extending in first to third directions that are not parallel to an upper surface of the upper substrate and that cross (e.g., intersect) with each other.

According to one or more embodiments, the space defined by the arrangement assistant is a space between the first to third linear portions and the quantum dot layer material may fill the space between the first to third linear portions.

According to one or more embodiments, the arrangement assistant may include a plurality of cylinders spaced apart from each other.

According to one or more embodiments, the space defined by the arrangement assistant is a space between the plurality of cylinders and the quantum dot layer material may fill the space between the plurality of cylinders.

According to one or more embodiments, the plurality of cylinders may be hollow.

According to one or more embodiments, at least one hollow interior of the plurality of hollow cylinders may be filled with air.

According to one or more embodiments, the quantum dot layer material may fill at least one hollow interior of the plurality of hollow cylinders.

According to one or more embodiments, the arrangement assistant may include a material having a different refractive index than the quantum dot layer material.

According to one or more embodiments, a method of manufacturing a color filter unit on an upper substrate includes forming a color filter layer on a lower surface of an upper substrate, and forming, on a lower surface of the color filter layer, a quantum dot layer including a quantum dot layer material and an arrangement assistant defining a space in which the quantum dot layer material is arranged, wherein the forming of the quantum dot layer includes forming the arrangement assistant on a lower surface of the color filter layer, injecting the quantum dot layer material into an area where the arrangement assistant is arranged, and curing the quantum dot layer material.

According to one or more embodiments, the arrangement assistant may include a porous layer including a plurality of spaces connected to each other.

According to one or more embodiments, the arrangement assistant may include a plurality of spheres.

According to one or more embodiments, the arrangement assistant may include first to third linear portions respectively extending in first to third directions that are not parallel to an upper surface of the upper substrate and that intersect with each other.

Other aspects and features other than those described above will become apparent from the following detailed description, the appended claims, and the accompanying drawings.

These general and particular aspects may be implemented by using systems, methods, computer programs, or any combinations of systems, methods, and computer programs.

### BRIEF DESCRIPTION OF THE DRAWINGS

The above and other aspects and features of certain embodiments will be more apparent from the following description taken in conjunction with the accompanying drawings, in which:

FIG. 1 is a plan view schematically illustrating a portion of a display apparatus according to an embodiment;

FIG. 2 is an equivalent circuit diagram of a pixel included in a display apparatus according to an embodiment;

FIG. 3 is a cross-sectional view schematically illustrating a portion of a display apparatus according to an embodiment;

FIG. 4 is a cross-sectional view schematically illustrating a portion of a display apparatus according to an embodiment;

FIG. 5 is a cross-sectional view schematically illustrating a portion of a color filter unit according to an embodiment;

FIG. 6 is a cross-sectional view schematically illustrating a portion of a color filter unit according to other embodiments;

FIG. 7 is a plan view schematically illustrating a portion of an arrangement assistant included in the color filter unit of FIG. 6;

FIG. 8 is a cross-sectional view schematically illustrating a portion of a color filter unit according to other embodiments;

FIG. 9 is a cross-sectional view schematically illustrating a portion of a color filter unit according to other embodiments;

FIG. 10 is a cross-sectional view schematically illustrating a portion of a color filter unit according to other embodiments;

FIG. 11 is a cross-sectional view schematically illustrating a portion of a color filter unit according to other embodiments;

FIG. 12 is a plan view schematically illustrating a portion of an arrangement assistant included in the color filter unit of FIG. 11;

FIG. 13 is a perspective view schematically illustrating a portion of an arrangement assistant included in the color filter unit of FIG. 11;

FIG. 14 is a cross-sectional view schematically illustrating a portion of a color filter unit according to other embodiments; and

FIG. 15 is a plan view schematically illustrating a portion of an arrangement assistant included in the color filter unit of FIG. 14.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. Throughout the disclosure, the expression “at least one of a, b or c” indicates only a, only b, only c, both a and b, both a and c, both b and c, all of a, b, and c, or variations thereof.

The disclosure may include various embodiments and modifications, and certain embodiments thereof are illustrated in the drawings and will be described herein in detail. The effects and features of the disclosure and the accomplishing methods thereof will become apparent from the embodiments described below in detail with reference to the accompanying drawings. However, the disclosure is not limited to the embodiments described below and may be embodied in various modes.

Hereinafter, embodiments will be described in detail with reference to the accompanying drawings, and in the following description, like reference numerals will denote like elements and redundant descriptions thereof will be omitted for conciseness.

It will be understood that although terms such as “first” and “second” may be used herein to describe various elements, these elements should not be limited by these terms and these terms are only used to distinguish one element from another element.

As used herein, the singular forms “a,” “an,” and “the” are intended to include the plural forms as well, unless the context clearly indicates otherwise.

Also, it will be understood that the terms “comprise,” “include,” and “have” used herein specify the presence of stated features or elements, but do not preclude the presence or addition of one or more other features or elements.

It will be understood that when a layer, region, or element is referred to as being “on” another layer, region, or element, it may be “directly on” the other layer, region, or element or may be “indirectly on” the other layer, region, or element with one or more intervening layers, regions, or elements therebetween.

Sizes of elements in the drawings may be exaggerated for convenience of description. In other words, because the sizes and thicknesses of elements in the drawings are arbitrarily illustrated for convenience of description, the disclosure is not limited thereto.

When a certain embodiment may be implemented differently, a particular process order may be performed differently from the described order. For example, two consecutively described processes may be performed substantially at the same time or may be performed in an order opposite to the described order.

As used herein, “A and/or B” represents the case of A, B, or A and B. Also, “at least one of A and B” represents the case of A, B, or A and B.

It will be understood that when a layer, region, or component is referred to as being “connected to” another layer, region, or component, it may be “directly connected to” the other layer, region, or component or may be “indirectly connected to” the other layer, region, or component with one or more intervening layers, regions, or components therebetween. For example, it will be understood that when a layer, region, or component is referred to as being “electrically connected to” another layer, region, or component, it may be “directly electrically connected to” the other layer, region, or component and/or may be “indirectly electrically connected to” the other layer, region, or component with one or more intervening layers, regions, or components therebetween.

The x axis, the y axis, and the z axis are not limited to three axes of the rectangular coordinate system and may be interpreted in a broader sense. For example, the x axis, the y axis, and the z axis may be perpendicular to one another or may represent different directions that are not perpendicular to one another.

Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. It will be understood that when an element or layer is referred to as being “on” or “adjacent to” another element or layer, it can be directly on or adjacent to the other element or layer, or one or more intervening elements or layers may be present. In contrast, when an element or layer is referred to as being “directly on” or “immediately adjacent to” another element or layer, there are no intervening elements or layers present.

In addition, it will also be understood that when an element or layer is referred to as being “between” two elements or layers, it can be the only element or layer between the two elements or layers, or one or more intervening elements or layers may also be present.

As used herein, the term “substantially,” “about,” and similar terms are used as terms of approximation and not as terms of degree, and are intended to account for the inherent deviations in measured or calculated values that would be recognized by those of ordinary skill in the art. Further, the use of “may” when describing embodiments of the present disclosure refers to “one or more embodiments of the present disclosure.” As used herein, the terms “use,” “using,” and “used” may be considered synonymous with the terms “utilize,” “utilizing,” and “utilized,” respectively.

The electronic or electric devices and/or any other relevant devices or components according to embodiments of the present disclosure described herein may be implemented utilizing any suitable hardware, firmware (e.g. an application-specific integrated circuit), software, or a combination of software, firmware, and hardware. For example, the various components of these devices may be formed on one integrated circuit (IC) chip or on separate IC chips. Further, the various components of these devices may be implemented on a flexible printed circuit film, a tape carrier package (TCP), a printed circuit board (PCB), or formed on one substrate. Further, the various components of these devices may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the spirit and scope of the embodiments of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

Hereinafter, embodiments will be described in detail with reference to the accompanying drawings.

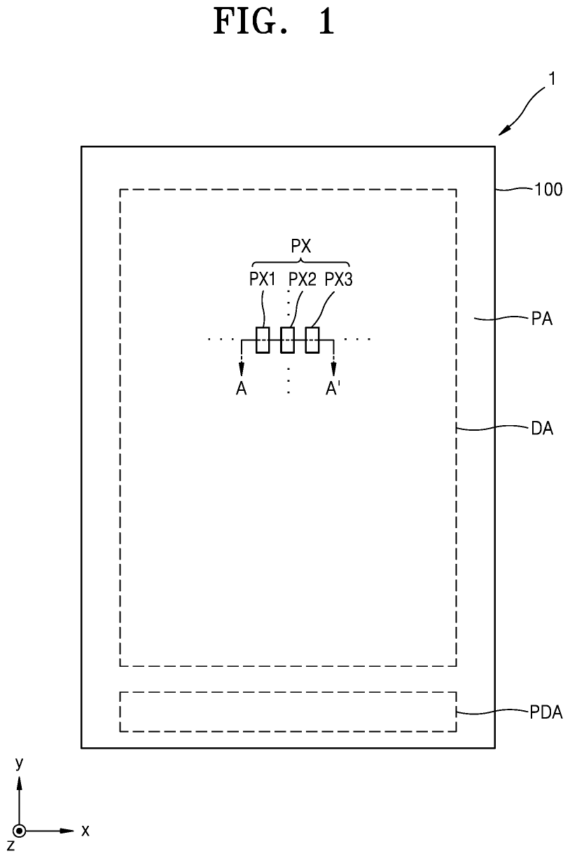

FIG. 1 is a plan view schematically illustrating a portion of a display apparatus according to an embodiment.

As illustrated in FIG. 1, a display apparatus 1 according to an embodiment may include a display area DA that emits light and a peripheral area PA that does not emit light. A lower substrate 100 (see FIG. 3) may include a first area corresponding to the display area DA and a second area corresponding to the peripheral area PA.

Although FIG. 1 illustrates the display apparatus 1 including the display area DA having a tetragonal shape, the display area DA may have any other suitable shape such as circular shape, elliptical shape, and/or polygonal shape.

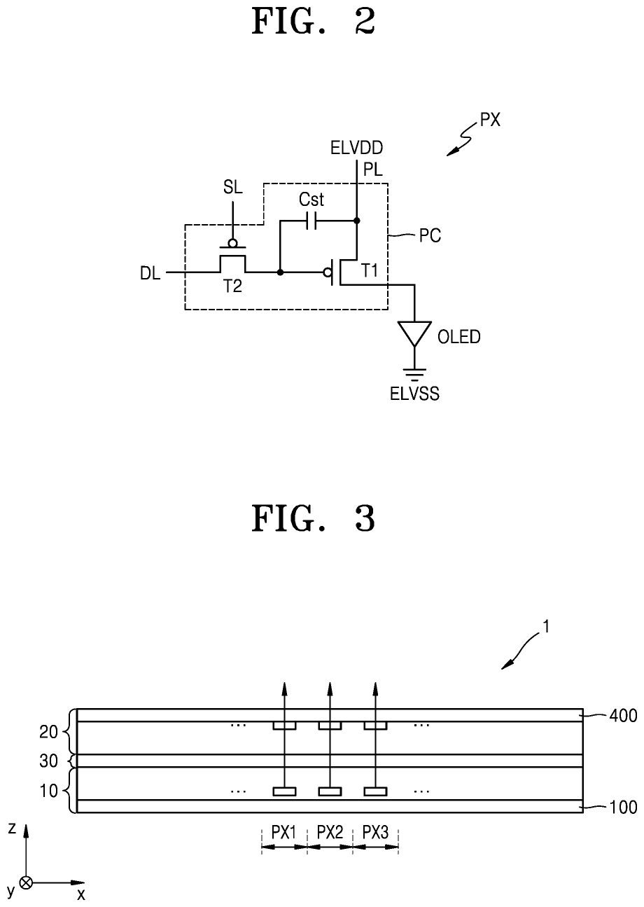

In the display area DA, pixels PX may be at a point where a scan line extending in the y-axis direction and a data line extending in the x-axis direction cross or intersect with each other. Each pixel PX may include a pixel circuit PC (see FIG. 2) connected to a scan line and a data line, and a display element connected to the pixel circuit PC.

The peripheral area PA may be around (e.g., surround) at least a portion of the display area DA. For example, the peripheral area PA may entirely surround the display area DA. Various lines for transmitting electrical signals to be applied to the display area DA may be in the peripheral area PA. Also, a portion of a circuit unit for controlling an electrical signal applied to the display area DA may be in the peripheral area PA.

The peripheral area PA may include a pad area PDA on at least one side thereof. A pad unit including a plurality of pads may be arranged on (or over) the pad area PDA. The plurality of pads included in the pad unit may be electrically and respectively connected to the pads of a printed circuit board to receive a signal input through the printed circuit board. For this purpose, the pad unit may include a plurality of pads. The plurality of pads may be exposed by not being covered by an insulating layer, to be electrically connected to a printed circuit board or the like.

Moreover, in some embodiments, the display apparatus 1 may include a component on one side thereof. The component may include an electronic element using light or sound. For example, the electronic element may include a sensor such as an infrared sensor for receiving and using light, a camera for receiving light to obtain an image, a sensor for outputting and detecting light or sound to measure a distance or recognize a fingerprint or the like, a miniature lamp for outputting light, or a speaker for outputting sound.

Hereinafter, an organic light emitting display apparatus will be described with reference to the display apparatus 1 according to an embodiment. However, the display apparatus of the disclosure is not limited thereto. That is, the display apparatus 1 of the disclosure may be an inorganic light emitting display apparatus or may be a display apparatus such as a quantum dot light emitting display apparatus. For example, an emission layer of the display element included in the display apparatus 1 may include an organic material and/or may include an inorganic material. Also, the emission layer of the display element included in the display apparatus 1 may include quantum dots, may include organic materials and quantum dots, and/or may include inorganic materials and quantum dots.

FIG. 2 is an equivalent circuit diagram of a pixel in a display apparatus according to an embodiment.

Referring to FIG. 2, each of pixels PX may be electrically connected to a pixel circuit PC. The pixel circuit PC may include one or more thin film transistors and one or more storage capacitors. In some embodiments, the pixel circuit PC may include a first thin film transistor T1, a second thin film transistor T2, and a storage capacitor Cst. A display element included in each pixel PX may emit light. For example, the display element may be, for example, an organic light emitting diode (OLED).

As a switching thin film transistor, the second thin film transistor T2 may be connected to a scan line SL and a data line DL, and a data voltage input from the data line DL may be transmitted to the first thin film transistor T1 according to a switching voltage input from the scan line SL. The storage capacitor Cst may be connected to the second thin film transistor T2 and a driving voltage line PL. The storage capacitor Cst may be configured to store a voltage corresponding to the difference between a voltage received from the second thin film transistor T2 and a first power voltage ELVDD supplied to the driving voltage line PL.

As a driving thin film transistor, the first thin film transistor T1 may be connected to the driving voltage line PL and the storage capacitor Cst and may be configured to control a driving current flowing from the driving voltage line PL through the display element in response to a voltage value stored in the storage capacitor Cst. The display element may emit light with a certain brightness according to the driving current. An opposite electrode (e.g., a cathode) of the display element may be supplied with a second power voltage ELVSS.

Although FIG. 2 illustrates that the pixel circuit PC includes two thin film transistors and one storage capacitor, the disclosure is not limited thereto. That is, the number of thin film transistors and the number of storage capacitors included in the pixel circuit PC may be variously modified according to the design of the pixel circuit PC. For example, in addition to the two thin film transistors described above, the pixel circuit PC may further include four or more thin film transistors. Also, in addition to the storage capacitor Cst described above, the pixel circuit PC may further include one or more storage capacitors.

FIG. 3 is a cross-sectional view schematically illustrating a portion of a display apparatus according to an embodiment.

As illustrated in FIG. 3, a display apparatus 1 according to an embodiment may include a display unit 10 and a color filter unit 20.

The display unit 10 may include the lower substrate 100. First to third pixels PX1 to PX3 may be arranged on (or over) the lower substrate 100 of the display unit 10. The first to third pixels PX1 to PX3 may be pixels respectively emitting different colors on (or over) the lower substrate 100. For example, the first pixel PX1 may emit light of a first color (e.g., blue), the second pixel PX2 may emit light of a second color (e.g., green), and the third pixel PX3 may emit light of a third color (e.g., red). For this purpose, the first pixel PX1 may include a first display element, the second pixel PX2 may include a second display element, and the third pixel PX3 may include a third display element. In some embodiments, the first to third display elements may respectively include emission layers emitting light of first to third colors. In other embodiments, the first to third display elements may include an emission layer emitting light of a first color, and the light emitted from each of the first to third pixels PX1 to PX3 may be controlled by the color filter unit 20.

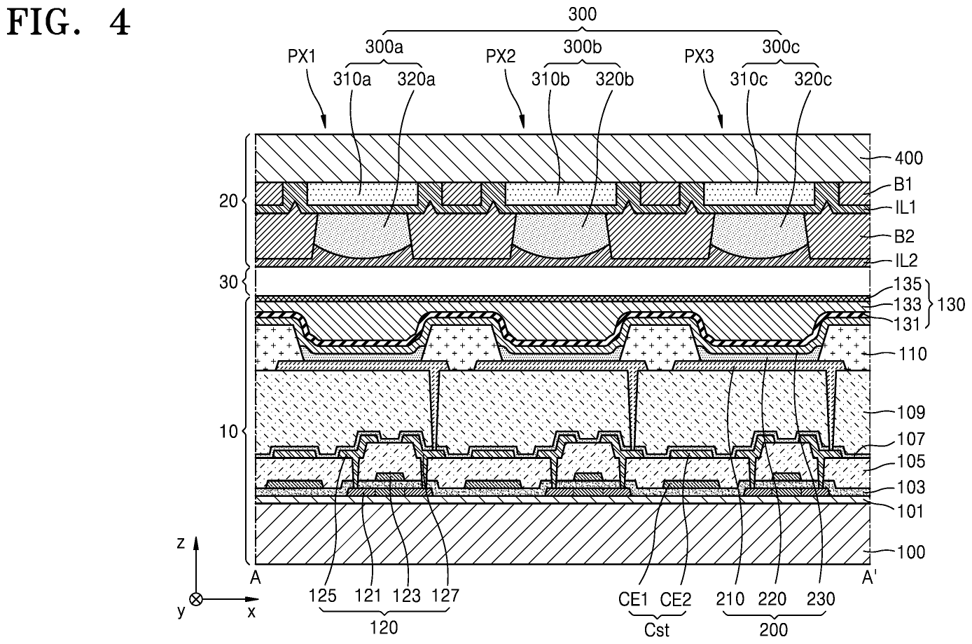

The color filter unit 20 may include an upper substrate 400. A filter unit 300 (see FIG. 4) may be (e.g., may extend) on (or over) a first surface of the upper substrate 400 of the color filter unit 20. Here, the “first surface” may refer to a surface (e.g., a lower surface) in the direction of the display unit 10 when the color filter unit 20 is arranged on (or over) the display unit 10.

In some embodiments, the color filter unit 20 may be separately manufactured by forming the filter unit 300 over the first surface of the upper substrate 400. In this case, the direction in which the upper substrate 400 is arranged in the process of manufacturing the color filter unit 20 is not limited. That is, the color filter unit 20 may be manufactured by forming the filter unit 300 on (or over) the first surface when the first surface as the lower surface of the upper substrate 400 is arranged to face downward (in the −z-axis direction), or may be manufactured by forming the filter unit 300 over the first surface when the first surface of the upper substrate 400 is arranged to face upward (in the +z-axis direction).

The display apparatus 1 may be manufactured by bonding the display unit 10 to the color filter unit 20 arranged on (or above) the display unit 10. In some embodiments, the display apparatus 1 may be manufactured by arranging first to third color filter units 300a to 300c included in the filter unit 300 of the color filter unit 20 to respectively correspond to the first to third pixels PX1 to PX3 and then bonding the display unit 10 to the color filter unit 20. Here, “corresponding” may refer to overlapping each other when viewed in a direction normal or perpendicular to the upper surface of the lower substrate 100 or the upper surface of the upper substrate 400.

In some embodiments, the display apparatus 1 may further include an adhesive layer 30 between the display unit 10 and the color filter unit 20 to assist the bonding between the display unit 10 and the color filter unit 20. For example, the adhesive layer 30 may include an optical clear adhesive (OCA), but is not limited thereto. Also, the adhesive layer 30 may include a filler. The filler may be between the display unit 10 and the color filter unit 20 to function as a buffer against external pressure or the like. The filler may include an organic material such as methyl silicone, phenyl silicone, and/or polyimide, an organic sealant such as urethane-based resin, epoxy-based resin, and/or acryl-based resin, and/or an inorganic sealant such as silicone, but is not limited thereto. In other embodiments, the adhesive layer 30 may be omitted.

In other embodiments, the filter unit 300 may be directly arranged on (or over) the display unit 10 without separately manufacturing the color filter unit 20. That is, the display apparatus 1 may be formed as an integral structure in which the filter unit 300 is directly arranged on (or over) the display unit 10 without including the upper substrate 400. In this case, quantum dot layers described below may be first formed on (or over) the display unit 10 and then color filter layers may be formed on (or over) the quantum dot layers.

FIG. 4 is a cross-sectional view schematically illustrating a portion of a display apparatus according to an embodiment.

FIG. 4 may correspond to a cross-sectional view of the display apparatus 1 taken along line A-A′ of FIG. 1. Although FIG. 4 illustrates that the first to third pixels PX1 to PX3 are adjacent to each other, the disclosure is not limited thereto. For example, components such as other lines may be between the first to third pixels PX1 to PX3. Accordingly, for example, the first pixel PX1 and the second pixel PX2 may not be adjacent pixels. Also, the cross-sections of the first to third pixels PX1 to PX3 in FIG. 4 may not be cross-sections in the same direction.

Referring to FIG. 3, the display apparatus 1, according to some embodiments may include the display unit 10, the color filter unit 20, and the adhesive layer 30 therebetween.

As shown in FIG. 4, the display unit 10 may include the lower substrate 100. The lower substrate 100 may include glass, metal, and/or polymer resin. When the lower substrate 100 is flexible and/or bendable, the lower substrate 100 may include, for example, a polymer resin such as polyethersulfone, polyacrylate, polyetherimide, polyethylene naphthalate, polyethylene terephthalate, polyphenylene sulfide, polyarylate, polyimide, polycarbonate, and/or cellulose acetate propionate. However, the lower substrate 100 may be variously modified such as including a multilayer structure including two layers including the polymer resin and a barrier layer between the two layers and including an inorganic material (e.g., silicon oxide, silicon nitride, and/or silicon oxynitride). This may also be similarly applied to an upper substrate 400 of the color filter unit 20 described further below.

A buffer layer 101 may be formed on (or over) the lower substrate 100. The buffer layer 101 may include an inorganic material such as silicon oxide, silicon nitride, and/or silicon oxynitride and may be formed as a single layer or as multiple layers. The buffer layer 101 may increase the smoothness of the upper surface of the lower substrate 100 and/or prevent or minimize the penetration of impurities or moisture from the outside of the lower substrate 100 into a semiconductor layer 121 of a thin film transistor 120.

A pixel circuit may be on (or over) the buffer layer 101, and a display element layer including first to third display elements electrically connected to the pixel circuit may be on (or over) the pixel circuit. That the first to third display elements are electrically connected to the pixel circuit may refer to that each of pixel electrodes of the first to third display elements is electrically connected to a thin film transistor included in the pixel circuit.

In some embodiments, the pixel circuit may include at least one thin film transistor 120 and at least one storage capacitor Cst.

The thin film transistor 120 may include the semiconductor layer 121 (including amorphous silicon, polycrystalline silicon, and/or an organic semiconductor material), a gate electrode 123, a source electrode 125, and a drain electrode 127.

The semiconductor layer 121 may be on (or over) the buffer layer 101 and may include amorphous silicon or polysilicon. As an illustrative example, the semiconductor layer 121 may include an oxide of at least one of indium (In), gallium (Ga), stannum (Sn), zirconium (Zr), vanadium (V), hafnium (Hf), cadmium (Cd), germanium (Ge), chromium (Cr), titanium (Ti), aluminum (Al), cesium (Cs), cerium (Ce), or zinc (Zn). Also, the semiconductor layer 121 may include a Zn oxide-based material such as a Zn oxide, an In—Zn oxide, and/or a Ga—In—Zn oxide. Also, the semiconductor layer 121 may include an In—Ga—Zn—O (IGZO), In—Sn—Zn—O (ITZO), and/or In—Ga—Sn—Zn—O (IGTZO) semiconductor containing a metal such as indium (In), gallium (Ga), and/or stannum (Sn) in ZnO. The semiconductor layer 121 may include a channel area and a source area and a drain area arranged on both sides of the channel area.

The gate electrode 123 may be on (or over) the semiconductor layer 121 to at least partially overlap the semiconductor layer 121. The gate electrode 123 may include various conductive materials including molybdenum (Mo), aluminum (Al), copper (Cu), titanium (Ti), and/or other suitable materials and may have various layered structures. For example, the gate electrode 123 may include a Mo layer and an Al layer or may have a multilayer structure of Mo/Al/Mo.

The source electrode 125 and the drain electrode 127 may also include various conductive materials including molybdenum (Mo), aluminum (Al), copper (Cu), titanium (Ti), and/or other suitable materials and may have various layered structures. For example, the source electrode 125 and the drain electrode 127 may include a Ti layer and an Al layer or may have a multilayer structure of Ti/Al/Ti. The source electrode 125 and the drain electrode 127 may be connected to the source area or the drain area of the semiconductor layer 121 through a contact hole.

Moreover, in order to secure the insulation between the semiconductor layer 121 and the gate electrode 123 (i.e., to insulate the semiconductor layer 121 from the gate electrode 123), a gate insulating layer 103 including an inorganic material such as silicon oxide, silicon nitride, and/or silicon oxynitride may be between the semiconductor layer 121 and the gate electrode 123. In addition, a first interlayer insulating layer 105 as a layer having a certain dielectric constant may be on (or over) the gate electrode 123, and the first interlayer insulating layer 105 may include an insulating layer including an inorganic material such as silicon oxide, silicon nitride, and/or silicon oxynitride. The source electrode 125 and the drain electrode 127 may be on (or over) the first interlayer insulating layer 105. The insulating layer including the inorganic material may be formed through chemical vapor deposition (CVD), atomic layer deposition (ALD), and/or other suitable process. This may also be similarly applied to the following embodiments and modifications thereof.

The storage capacitor Cst may include a lower electrode CE1 and an upper electrode CE2. The lower electrode CE1 and the upper electrode CE2 overlap each other with the first interlayer insulating layer 105 therebetween to form a capacitor. In this case, the first interlayer insulating layer 105 may function as a dielectric layer of the storage capacitor Cst.

The lower electrode CE1 may be on the same layer as the gate electrode 123. The lower electrode CE1 may include the same material as the gate electrode 123, and may include, for example, various conductive materials including molybdenum (Mo), aluminum (Al), copper (Cu), titanium (Ti), and/or other suitable material(s), and may have various layered structures (e.g., a multilayer structure of Mo/Al/Mo). The upper electrode CE2 may be on the same layer as the source electrode 125 and the drain electrode 127. The upper electrode CE2 may include the same material as the source electrode 125 and the drain electrode 127, and may include, for example, various conductive materials including molybdenum (Mo), aluminum (Al), copper (Cu), titanium (Ti), and/or other suitable material(s), and may have various layered structures (e.g., a multilayer structure of Ti/Al/Ti).

A planarization layer 109 may be arranged on (or over) the thin film transistor 120. When an organic light emitting diode, as an example of the first to third display elements, is located on (or over) the thin film transistor 120, the planarization layer 109 may function to substantially planarize an upper portion of a protection layer 107 covering the thin film transistor 120. The planarization layer 109 may include, for example, a general-purpose polymer such as benzocyclobutene (BCB), polyimide, hexamethyldisiloxane (HMDSO), polymethylmethacrylate (PMMA), and/or polystyrene (PS), a polymer derivative having a phenolic group, an acrylic polymer, an imide-based polymer, an aryl ether -based polymer, an amide-based polymer, a fluorine-based polymer, a p-xylene-based polymer, a vinyl alcohol-based polymer, or any blend thereof. In FIG. 4, for convenience, the planarization layer 109 is illustrated as a single layer; however, the planarization layer 109 may be multiple layers and may be variously modified.

The first to third display elements may be on (or over) the planarization layer 109. In some embodiments, each of the first to third display elements may include an organic light emitting diode 200 including a pixel electrode 210, an opposite electrode 230, and an intermediate layer 220 therebetween and including an emission layer.

The pixel electrode 210 may be electrically connected to the thin film transistor 120 by contacting any one of the source electrode 125 and the drain electrode 127 through an opening portion (e.g., a contact hole) formed in the planarization layer 109 and/or other relevant layer(s). The pixel electrode 210 may include a (semi)transparent electrode and/or a reflective electrode. In some embodiments, the pixel electrode 210 may include a reflective layer including Ag, Mg, Al, Pt, Pd, Au, Ni, Nd, Ir, Cr, or any compound thereof and a transparent or semitransparent electrode layer formed on (or over) the reflective layer. The transparent or semitransparent electrode layer may include at least one of indium tin oxide (ITO), indium zinc oxide (IZO), zinc oxide (ZnO), indium oxide (In₂O₃), indium gallium oxide (IGO), or aluminum zinc oxide (AZO). Also, the pixel electrode 210 may have a stack structure of ITO/Ag/ITO.

Moreover, a pixel definition layer 110 may be on (or over) the planarization layer 109. The pixel definition layer 110 may define a pixel (or an emission area) by having an opening corresponding to each of the pixels PX. In this case, the opening may expose at least a portion of the center of the pixel electrodes 210. For example, the pixel definition layer 110 may be between the first display element and the second display element, between the second display element and the third display element, and between the first display element and the third display element. Also, the pixel definition layer 110 may increase the distance between the edge of the pixel electrodes 210 and the opposite electrode 230 on (or over) the pixel electrodes 210 to prevent or reduce the possibility of an arc or the like from occurring at the edge of the pixel electrodes 210. The pixel definition layer 110 may include at least one organic insulating material among polyamide, polyimide, acryl resin, benzocyclobutene, and/or phenol resin and may be formed by spin coating or other suitable process.

In some embodiments, as illustrated in FIG. 4, the intermediate layer 220 may include a layer integrated on (or over) the pixel electrodes 210 of the first to third display elements. In other embodiments, the intermediate layer 220 may include a layer patterned to correspond to each of the pixel electrodes 210 of the first to third display elements. In any case, the intermediate layer 220 may include a first color emission layer emitting light of a wavelength belonging to a first wavelength band. The first color emission layer may be integrated on (or over) the pixel electrodes 210 of the first to third display elements or may be patterned to correspond to each of the pixel electrodes 210 of the first to third display elements. The first color emission layer may emit light of a wavelength belonging to the first wavelength band. For example, the first wavelength band may be about 450 nm to about 495 nm and the first color may be blue; however, the disclosure is not limited thereto.

The intermediate layer 220 may include a low molecular weight or high molecular weight material. When the intermediate layer 220 includes a low molecular weight material, the intermediate layer 220 may include a structure in which a hole injection layer (HIL), a hole transport layer (HTL), an emission layer (EML), an electron transport layer (ETL), an electron injection layer (EIL), and/or other suitable layer(s) are stacked in a single or complex structure and may be formed by vacuum deposition. When the intermediate layer 220 includes a high molecular weight material, the intermediate layer 220 may include a structure including an HTL and an EML. In this case, the HTL may include poly(3,4-ethylenedioxythiophene) (PEDOT) and the emission layer may include a high molecular weight material such as polyphenylenevinylene (PPV) and/or polyfluorene. The intermediate layer 220 may be formed by screen printing, inkjet printing, deposition, laser induced thermal imaging (LITI), and/or other suitable process, but is not limited thereto.

The opposite electrode 230 may be on (or over) a display area. As an illustrative example, the opposite electrode 230 may include an integral layer to cover the entire surface of the display area and may be arranged on (or over) the display area. That is, the opposite electrode 230 may be integrally formed on (or over) the first to third display elements to correspond to a plurality of pixel electrodes 210. In this case, the opposite electrode 230 may be formed to cover the display area and extend to a portion of a non-display area outside the display area. As another illustrative example, the opposite electrode 230 may be patterned and formed to correspond to each of a plurality of pixel electrodes 210.

The opposite electrode 230 may include a transparent electrode or a reflective electrode. In some embodiments, the opposite electrode 230 may include a transparent or semitransparent electrode and may include a thin metal layer having a low work function and including Li, Ca, LiF/Ca, LiF/Al, Al, Ag, Mg, or any compound thereof. Also, a transparent conductive oxide (TCO) layer such as ITO, IZO, ZnO, and/or In₂O₃ may be further included in addition to the thin metal layer.

The organic light emitting diode described above may be easily damaged by moisture and/or oxygen from the outside and therefore may be protected by being covered with an encapsulation layer 130. The encapsulation layer 130 may include at least one organic encapsulation layer and at least one inorganic encapsulation layer. For example, the encapsulation layer 130 may include a first inorganic encapsulation layer 131, an organic encapsulation layer 133, and a second inorganic encapsulation layer 135.

The first inorganic encapsulation layer 131 may cover the opposite electrode 230 and may include silicon oxide, silicon nitride, and/or silicon trioxynitride. Other layers such as a capping layer may be between the first inorganic encapsulation layer 131 and the opposite electrode 230. Because the first inorganic encapsulation layer 131 is formed along a structure thereunder and thus an upper surface thereof is not flat, the organic encapsulation layer 133 may be formed to cover the first inorganic encapsulation layer 131 such that the upper surface thereof may be flat. The organic encapsulation layer 133 may include at least one of polyethylene terephthalate, polyethylene naphthalate, polycarbonate, polyimide, polyethylene sulfonate, polyoxymethylene, polyarylate, or hexamethyldisiloxane. The second inorganic encapsulation layer 135 may cover the organic encapsulation layer 133 and may include silicon oxide, silicon nitride, and/or silicon trioxynitride.

Although a crack may occur in the encapsulation layer 130 through the above multilayer structure, the crack may not be connected between the first inorganic encapsulation layer 131 and the organic encapsulation layer 133 or between the organic encapsulation layer 133 and the second inorganic encapsulation layer 135. Accordingly, the formation of a path through which external moisture or oxygen may penetrate thereinto may be prevented or minimized.

The color filter unit 20 may be arranged on (or over) the display unit 10. The color filter unit 20 may include an upper substrate 400 and a filter unit 300 arranged on (or over) a first surface of the upper substrate 400. Here, the “first surface” may refer to a surface (lower surface) in the direction of the display unit 10 when the color filter unit 20 is arranged on (or over) the display unit 10.

In some embodiments, the filter unit 300 may include first to third color filter units 300a to 300c respectively corresponding to the first to third pixels PX1 to PX3. The first to third color filter units 300a to 300c may respectively overlap the emission layers of the intermediate layers 220 and/or the pixel electrodes 210 of the first to third display elements in a plan view (e.g., when viewed in a direction (e.g., an z-direction) normal to the lower substrate 100 of the display unit 10 or the upper substrate 400 of the color filter unit 20). The first to third color filter units 300a to 300c may respectively filter the light emitted from the first to third display elements.

In some embodiments, the first color filter unit 300a may include a first color filter layer 310a and a transparent layer 320a, the second color filter unit 300b may include a second color filter layer 310b and a second color quantum dot layer 320b, and the third color filter unit 300c may include a third color filter layer 310c and a third color quantum dot layer 320c.

The first color filter layer 310a may transmit only light of a wavelength belonging to about 450 nm to about 495 nm, the second color filter layer 310b may transmit only light of a wavelength belonging to about 495 nm to about 570 nm, and the third color filter layer 310c may transmit only light of a wavelength belonging to about 630 nm to about 780 nm. The first to third color filter layers 310a to 310c may reduce the reflection of external light in the display apparatus 1.

For example, when external light reaches the first color filter layer 310a, only light of the preset wavelength described above may be transmitted through the first color filter layer 310a and light of other wavelengths may be absorbed by the first color filter layer 310a. Thus, among the external light incident on the display apparatus 1, only light of the preset wavelength described above may be transmitted through the first color filter layer 310a and a portion of the light may be reflected from the opposite electrode 230 thereunder or the pixel electrode 210 of the first display element and then emitted to the outside. As a result, because only a portion of the external light incident on a location where the first pixel PX1 is located may be reflected to the outside, the external light reflection may be reduced. This description may also be similarly applied to the second color filter layer 310b and the third color filter layer 310c.

The second color quantum dot layer 320b may convert light of a wavelength belonging to the first wavelength band generated in the intermediate layer 220 of the second display element into light of a wavelength belonging to a second wavelength band. For example, when light of a wavelength belonging to about 450 nm to about 495 nm is generated in the intermediate layer 220 of the second display element, the second color quantum dot layer 320b may convert the light into light of a wavelength belonging to about 495 nm to about 570 nm. Accordingly, the second pixel PX2 may emit light of a wavelength belonging to about 495 nm to about 570 nm to the outside.

The third color quantum dot layer 320c may convert light of a wavelength belonging to the first wavelength band generated in the intermediate layer 220 of the third display element into light of a wavelength belonging to a third wavelength band. For example, when light of a wavelength belonging to about 450 nm to about 495 nm is generated in the intermediate layer 220 of the third display element, the third color quantum dot layer 320c may convert the light into light of a wavelength belonging to about 630 nm to about 780 nm. Accordingly, the third pixel PX3 may emit light of a wavelength belonging to about 630 nm to about 780 nm to the outside.

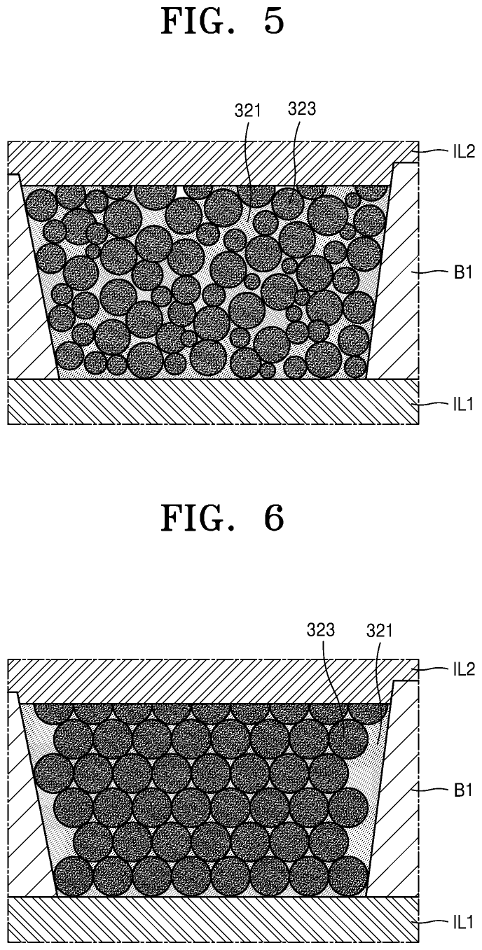

Moreover, each of the second color quantum dot layer 320b and the third color quantum dot layer 320c may include an arrangement assistant 321 and a quantum dot layer material 323, as shown, for example, in FIG. 5. The arrangement assistant 321 may assist the arrangement of the quantum dot layer material 323, thereby defining an area in which the quantum dot layer material 323 is arranged. The arrangement assistant 321 will be described below in more detail with reference to FIGS. 5 to 15.

The quantum dot layer material 323 may have a form in which quantum dots are distributed in a resin. The resin included in the quantum dot layer material 323 may include any transparent material. For example, the quantum dot layer material 323 may include a polymer resin such as silicone resin, epoxy resin, acryl, benzocyclobutene (BCB), and/or hexamethyldisiloxane (HMDSO).

The quantum dot included in the quantum dot layer material 323 may have a size of several nanometers, and the wavelength of light after conversion may vary depending on the particle size of the quantum dot. That is, the quantum dot may control the color of light emitted according to the particle size, and accordingly, the quantum dot may have various emission colors such as blue, red, and green.

The quantum dot may have a full width at half maximum (FWHM) of an emission wavelength spectrum of about 45 nm or less, for example, about 40 nm or less or about 30 nm or less, and in these ranges, the color purity and/or the color reproducibility thereof may be improved. Also, because the light emitted through the quantum dot is emitted in all directions, the optical viewing angle thereof may be improved. Also, the shapes of the quantum dots may be those generally used in the art and may include, but not limited to, spherical, pyramidal, multi-arm, and/or cubic nanoparticles, nanotubes, nanowires, nanofibers, nanoplate particles, and/or other suitable structure(s). Also, the quantum dot may include a semiconductor material such as cadmium sulfide (CdS), cadmium telluride (CdTe), zinc sulfide (ZnS), and/or indium phosphide (InP).

Moreover, the first color filter unit 300a may include a transparent layer 320a without including a quantum dot layer. For example, each of the first to third display elements of the display unit 10 may include an intermediate layer 220 including a first color emission layer emitting light of a wavelength belonging to the first wavelength band. In this case, the first pixel PX1 may emit light of a wavelength belonging to the first wavelength band generated in the intermediate layer 220 to the outside without wavelength conversion. Thus, because the first pixel PX1 does not require a quantum dot layer, the first color filter unit 300a may include a transparent layer 320a including a transparent resin, instead of a quantum dot layer.

The transparent layer 320a may include a polymer resin such as silicone resin, epoxy resin, acryl, benzocyclobutene (BCB), and/or hexamethyldisiloxane (HMDSO). Also, in other embodiments, the transparent layer 320a may include scattering particles.

Moreover, first partition walls B1 may be between the first to third color filter layers 310a to 310c, and second partition walls B2 may be between the transparent layer 320a, the second color quantum dot layer 320b, and the third color quantum dot layer 320c, as shown, for example in FIG. 4. The first partition walls B1 and the second partition walls B2 may define first to third color areas, and the first to third color areas may respectively correspond to the first to third pixels PX1 to PX3.

The first partition walls B1 and the second partition walls B2 may include a material (e.g., a photoresist) that is chemically changed when irradiated with light. For example, the first partition walls B1 and the second partition walls B2 may include a negative photoresist such as aromatic bis-azide, methacrylic acid ester, and/or cinnamic acid ester and may include a positive photoresist such as polymethyl methacrylate, naphthquinone diazide, and/or polybutene-1-sulfone; however, the disclosure is not limited thereto. Also, in other embodiments, the first partition walls B1 and the second partition walls B2 may include a black matrix, a black pigment, a metal material, and/or the like to function as a light blocking layer and may include a reflective material such as Al and/or Ag to increase light efficiency.

Also, a first protection layer IL1 may be between the color filter layer and the quantum dot layer and/or between the color filter layer and the transparent layer, and a second protection layer IL2 may be arranged to cover a surface of the transparent layer and/or the quantum dot layer in the direction of the display unit 10. The first protection layer IL1 and the second protection layer IL2 may prevent or reduce damage to the quantum dot layers in a manufacturing process or during use after manufacturing.

The first protection layer IL1 and the second protection layer IL2 may include a transparent inorganic insulating material such as silicon oxide, silicon nitride, and/or silicon oxynitride. Also, the first protection layer IL1 and the second protection layer IL2 may include an organic material layer including at least one of polyethylene terephthalate, polyethylene naphthalate, polycarbonate, polyimide, polyethylene sulfonate, polyoxymethylene, polyarylate, and/or hexamethyldisiloxane. Also, the first protection layer IL1 and the second protection layer IL2 may be integrally formed on (or over) the entire surface of the upper substrate 400.

In the display apparatus 1 including the filter unit 300 described above, the first pixel PX1 may emit light of the first wavelength band to the outside, and the second pixel PX2 may emit light of the second wavelength band to the outside, and the third pixel PX3 may emit light of the third wavelength band to the outside. Accordingly, the display apparatus 1 may display a full-color image.

Moreover, the quantum dot layer and/or the transparent layer of the color filter unit 20 may be formed by using an inkjet process. In some embodiments, the second partition walls B2 defining an area in which the quantum dot layer and/or the transparent layer are to be formed may be formed. Subsequently, the quantum dot layer material 323 and/or a transparent layer material in the form of ink may be injected and cured between the second partition walls B2, thereby forming the quantum dot layer and/or the transparent layer. When the inkjet process is applied as such, there is a problem in that the quantum dot layer and/or the transparent layer may have a nonuniform shape or particles included in the quantum dot layer material and/or the transparent layer material may be nonuniformly distributed.

In order to solve this problem, in some embodiments, the quantum dot layer and/or the transparent layer may include an arrangement assistant 321. The arrangement assistant 321 may assist the arrangement of the quantum dot layer material 323 and/or the transparent layer material, thereby functioning to uniformly form the quantum dot layer and/or the transparent layer. In some embodiments, the arrangement assistant 321 may be a structure having a space in which the quantum dot layer material 323 and/or the transparent layer material may be arranged, and may function as a frame of the quantum dot layer and/or the transparent layer. Hereinafter, the quantum dot layer including the arrangement assistant 321 and the quantum dot layer material 323 will be described further; however, the following description may also be similarly applied to the transparent layer.

A method of manufacturing a color filter unit 20 according to an embodiment may include an operation of forming a color filter layer on (or over) the lower surface of an upper substrate 400 and an operation of forming a quantum dot layer on (or over) the lower surface of the color filter layer. Also, the operation of forming the quantum dot layer may include an operation of forming an arrangement assistant 321 on (or over) the lower surface of the color filter layer, an operation of injecting a quantum dot layer material 323 into an area where the arrangement assistant 321 is arranged, and an operation of curing the injected quantum dot layer material 323.

In some embodiments, an arrangement assistant 321 may be formed between the second partition walls B2 arranged on (or over) the lower surface of the color filter layer, and a quantum dot layer material 323 in the form of ink may be injected into an area where the arrangement assistant 321 is arranged, by using an inkjet process. The quantum dot layer material 323 in the form of ink may be arranged to fill a space of the arrangement assistant 321 in which the quantum dot layer material 323 may be arranged. That is, the quantum dot layer material 323 in the form of ink may be arranged to fill a space of the arrangement assistant 321, in which the quantum dot layer material 323 may be arranged, while flowing in a direction toward the upper substrate 400 from a location distant from the upper substrate 400.

Accordingly, because the quantum dot layer material 323 may be arranged along a structure included in the arrangement assistant 321, the quantum dot layer material 323 may be uniformly arranged without being concentrated in a particular area and may prevent or reduce the possibility of the quantum dot layer from being formed in a non-uniform shape due to contraction during a curing process thereof. Also, because the quantum dots included in the quantum dot layer material 323 may be uniformly distributed in the quantum dot layer without being concentrated in a particular area, the display quality thereof may be improved.

The arrangement assistant 321 may include a transparent resin or a semitransparent resin. In some embodiments, the arrangement assistant 321 may include a material having a different refractive index than the quantum dot layer material 323. Accordingly, the arrangement assistant 321 may more effectively scatter incident light. In other embodiments, because the arrangement assistant 321 may scatter incident light, the quantum dot layer may not include an additional scatterer. In this case, when the quantum dot layer material is injected, non-uniform distribution of particles in the quantum dot layer material may be minimized or reduced.

Hereinafter, various embodiments of the structure included in the arrangement assistant 321 will be described in detail with reference to FIGS. 5 to 15. For convenience, FIGS. 5 to 15 illustrate a quantum dot layer arranged on (or over) any pixel; however, the following description may be similarly applied to at least a portion of a transparent layer and/or at least some of the quantum dot layers arranged in any pixel included in a display apparatus. Also, like reference numerals in the drawings may refer to like elements, and thus, redundant descriptions already given above are omitted for conciseness.

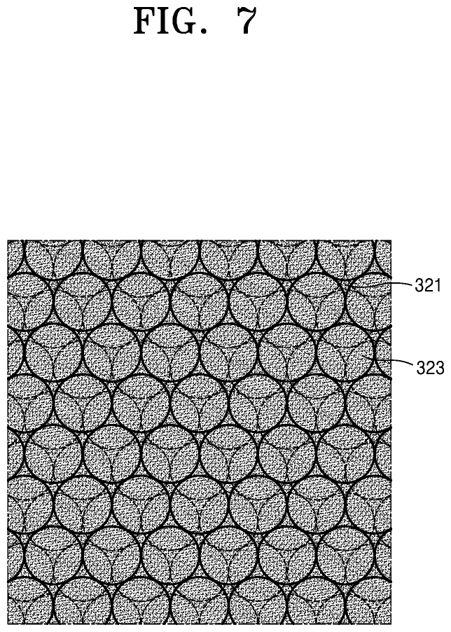

FIG. 5 is a cross-sectional view schematically illustrating a portion of a color filter unit according to an embodiment, FIG. 6 is a cross-sectional view schematically illustrating a portion of a color filter unit according to other embodiments, and FIG. 7 is a plan view schematically illustrating a portion of an arrangement assistant included in the color filter unit of FIG. 6.

As illustrated in FIG. 5, an arrangement assistant 321 may include a porous layer including a plurality of spaces connected to each other. In this case, a quantum dot layer material 323 may be arranged to fill a plurality of spaces of a porous layer. The porous layer may be a layer including a plurality of pores before the quantum dot layer material 323 is injected, and the plurality of pores may correspond to a plurality of spaces that may be filled with the quantum dot layer material 323.

The shape, size, number, and arrangement of the plurality of spaces in the porous layer are not limited. For example, the plurality of spaces in the porous layer may have a spherical shape. Also, the plurality of spaces may have a non-uniform size as illustrated in FIG. 5 or may have a uniform size as illustrated in FIGS. 6 and 7. The porous layer may include a transparent resin or a semitransparent resin. In some embodiments, the porous layer may include a material having a different refractive index than the quantum dot layer material 323.

In some embodiments, the porous layer may be formed by a sacrificial template method. In some embodiments, a sacrificial template contributing to formation of the porous layer may be between second partition walls B2, and a liquid arrangement assistant material may be injected between the second partition walls B2. The injected arrangement assistant material may fill in-between spaces of the sacrificial template. Subsequently, when the sacrificial template is selectively removed while leaving only the arrangement assistant material, an arrangement assistant 321 including a plurality of spaces corresponding to the shape in which the sacrificial template has been arranged may be formed. That is, the shape, size, number, and arrangement of the plurality of spaces included in the arrangement assistant 321 may depend on the shape, size, number, and arrangement of sacrificial templates. For example, when the sacrificial template includes a plurality of spheres, the arrangement assistant 321 may include a plurality of spaces having a spherical shape and connected to each other. Also, when the sacrificial template includes a plurality of spheres having a non-uniform size, the arrangement assistant 321 may be formed as in FIG. 5, and when the sacrificial template includes a plurality of spheres having a uniform size, the arrangement assistant 321 may be formed as in FIGS. 6 and 7.

This sacrificial template may include polystyrene. As an illustrative example, the sacrificial template may include atactic polystyrene that does not have a melting point, is in a liquid state at temperatures equal to or higher than the glass transition temperature, and undergoes rapid decomposition of main chains when reaching the pyrolysis temperature thereof. However, the disclosure is not limited thereto, and the sacrificial template may include any material that is characterized as being removable under a different condition than the arrangement assistant material.

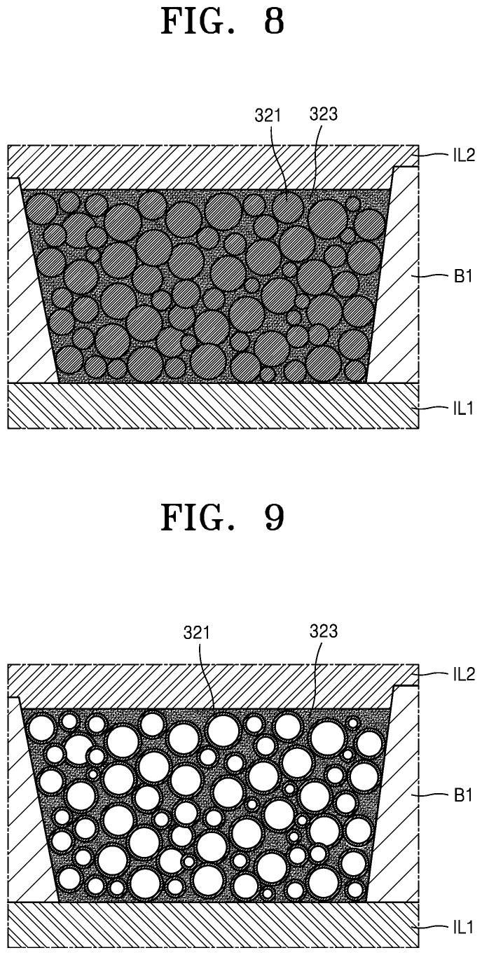

FIG. 8 is a cross-sectional view schematically illustrating a portion of a color filter unit according to other embodiments.

As illustrated in FIG. 8, an arrangement assistant 321 may include a plurality of spheres. In this case, a quantum dot layer material 323 may be arranged to fill a space between a plurality of spheres.

The size, number, and arrangement of the plurality of spheres are not limited. For example, FIG. 8 illustrates a case where the plurality of spheres have nonuniform sizes or substantially nonuniform sizes; however, the plurality of spheres may have uniform sizes or substantially uniform sizes. In any case, the quantum dot layer material 323 may be arranged to fill a space connected between the plurality of spheres. The plurality of spheres may include a transparent resin or a semitransparent resin. In some embodiments, the plurality of spheres may include a material having a different refractive index than the quantum dot layer material 323. Also, the plurality of spheres may include silica-ball, silica-gel, and/or other suitable material(s).

FIGS. 9 and 10 are cross-sectional views schematically illustrating a portion of a color filter unit according to other embodiments.

As illustrated in FIGS. 9 and 10, an arrangement assistant 321 may include a plurality of hollow spheres. FIGS. 9 and 10 may correspond to a case where the plurality of spheres included in the arrangement assistant 321 of FIG. 8 are hollow (i.e., have a hollow interior). As in FIG. 8, in FIGS. 9 and 10, a quantum dot layer material 323 may be arranged to fill a space between the plurality of hollow spheres.

The hollow interior of the plurality of hollow spheres may be kept empty or may be filled with the quantum dot layer material 323 as necessary. Accordingly, optical properties such as the refractive index and scattering properties of the quantum dot layer may be adjusted.

In some embodiments, the hollow interior of the plurality of hollow spheres may be filled with air as illustrated in FIG. 9. That is, the quantum dot layer material 323 may not be arranged in the hollow interior of the plurality of hollow spheres. In other embodiments, the quantum dot layer material 323 may fill the hollow interior of the plurality of hollow spheres as illustrated in FIG. 10. In such cases, as a liquid quantum dot layer material 323 flows in a direction toward the upper substrate 400 from a location distant from the upper substrate 400, a portion thereof may fill the space between the plurality of hollow spheres and the other portion thereof may fill the hollow interior of the plurality of hollow spheres. For this purpose, each of the plurality of hollow spheres may include at least one opening. The quantum dot layer material 323 may be arranged in the hollow interior of the plurality of hollow spheres through at least one opening of the plurality of hollow spheres.

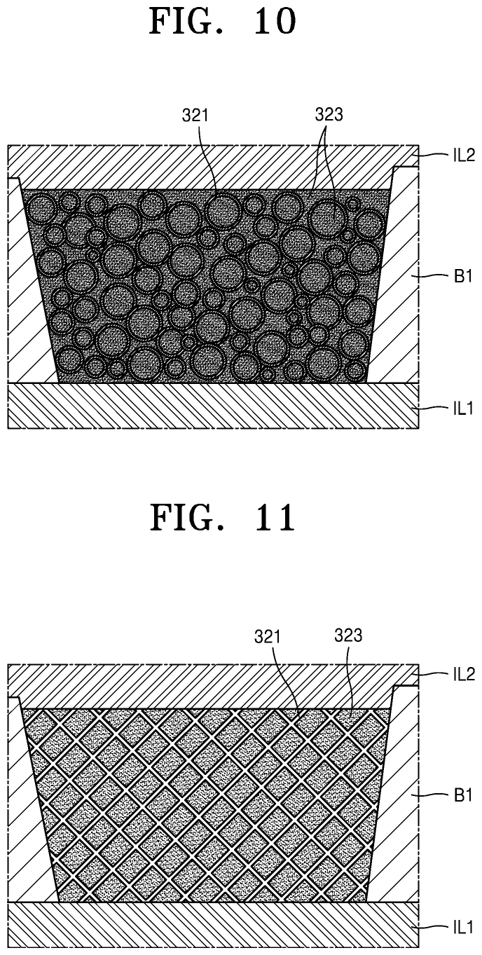

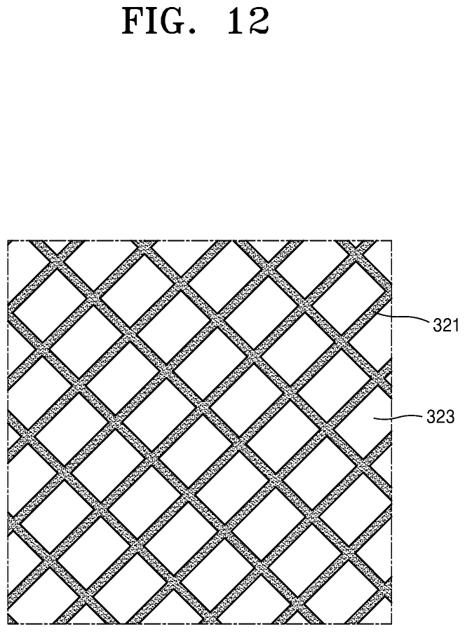

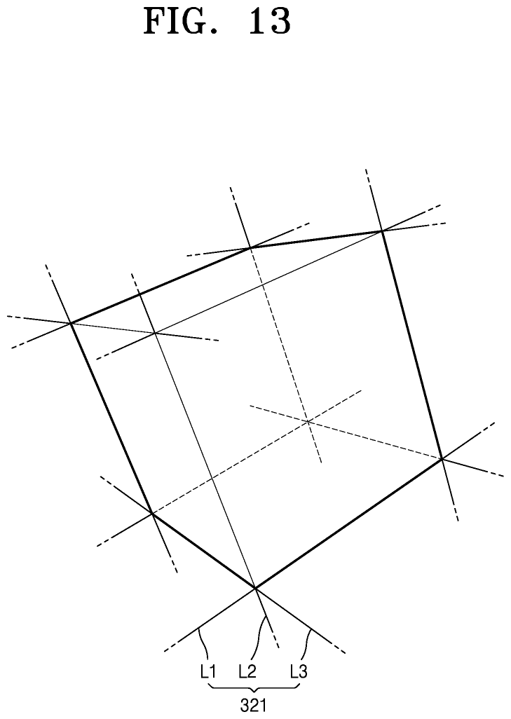

FIG. 11 is a cross-sectional view schematically illustrating a portion of a color filter unit according to other embodiments, FIG. 12 is a plan view schematically illustrating a portion of an arrangement assistant included in the color filter unit of FIG. 11, and FIG. 13 is a perspective view schematically illustrating a portion of an arrangement assistant included in the color filter unit of FIG. 11.

As illustrated in FIGS. 11 to 13, an arrangement assistant 321 may include first to third linear portions L1 to L3 respectively extending in first to third directions that are not parallel to the upper surface of the upper substrate 400 and intersect with each other. In such cases, a quantum dot layer material 323 may be arranged to fill a space between the first to third linear portions L1 to L3.

The thickness, number, and arrangement of the first to third linear portions L1 to L3 are not limited. For example, FIGS. 11 to 13 illustrate a case where the first to third linear portions L1 to L3 have a uniform thickness and are spaced apart at uniform intervals; however, the first to third linear portions L1 to L3 may have a nonuniform thickness or may be spaced apart at nonuniform intervals. In any case, the quantum dot layer material 323 may be arranged to fill a space between the first to third linear portions L1 to L3.

The first to third linear portions L1 to L3 may cross or intersect with each other and form a three-dimensional grid structure. For example, the three-dimensional grid structure formed by the first to third linear portions L1 to L3 may include a repeated arrangement of a plurality of cube-shaped or rectangular parallelepiped-shaped unit structures. For convenience, FIG. 13 illustrates one unit structure; however, the three-dimensional grid structure may include a regular arrangement of a plurality of unit structures. In such cases, each of the first to third linear portions L1 to L3 forming the unit structure may be formed to be inclined by a particular angle so as not to be parallel to the upper surface of the upper substrate 400.

In some embodiments, the first to third linear portions L1 to L3 may be formed by laser interference lithography. In some embodiments, a liquid arrangement assistant material may be between the second partition walls B2, and a laser beam may be irradiated on (or over) the arrangement assistant material. The irradiated laser beam may pass through the arrangement assistant material. The laser beam may be absorbed by the arrangement assistant material overlapping the path of the laser beam. The first to third linear portions L1 to L3 included in the arrangement assistant 321 may be formed by being cured by the energy of the laser beam absorbed by the arrangement assistant material located in an area where the laser beam is absorbed. In such cases, as described above, because the first to third linear portions L1 to L3 are not parallel to the upper surface of the upper substrate 400, the first to third linear portions L1 to L3 may be formed by adjusting only the angle of the laser beam irradiated when a laser irradiator is arranged on (or over) the arrangement assistant material. Moreover, in other embodiments, contrary to the above method, the first to third linear portions L1 to L3 may be formed by removing only the area where the laser beam is irradiated.

The first to third linear portions L1 to L3 may include a transparent resin or a semitransparent resin. In some embodiments, the first to third linear portions L1 to L3 may include a material having a different refractive index than the quantum dot layer material 323.

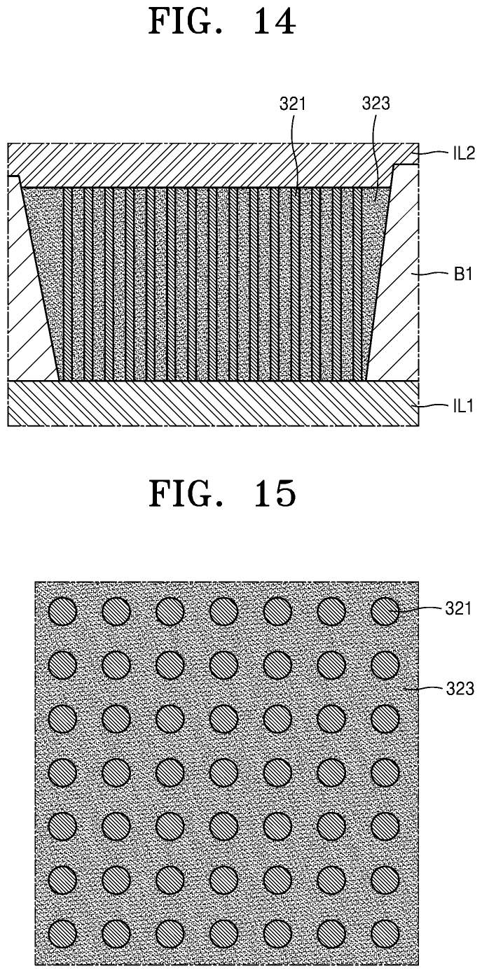

FIG. 14 is a cross-sectional view schematically illustrating a portion of a color filter unit according to other embodiments, and FIG. 15 is a plan view schematically illustrating a portion of an arrangement assistant included in the color filter unit of FIG. 14.

As illustrated in FIGS. 14 and 15, an arrangement assistant 321 may include a plurality of cylinders spaced apart from each other. In such cases, a quantum dot layer material 323 may be arranged to fill a space between the plurality of cylinders.

The diameter, number, and arrangement of the plurality of cylinders are not limited. For example, FIGS. 14 and 15 illustrate a case where the plurality of cylinders have a uniform diameter; however, the plurality of cylinders may have a nonuniform diameter. In such cases, the quantum dot layer material 323 may be arranged to fill a space between the plurality of cylinders.

Moreover, the plurality of cylinders may be formed by laser interference lithography like the first to third linear portions L1 to L3 described above with reference to FIGS. 11 to 13. Also, the plurality of cylinders may include a transparent resin or a semitransparent resin. In some embodiments, the plurality of cylinders may include a material having a different refractive index than the quantum dot layer material 323.

In some embodiments, the plurality of cylinders may include hollow cylinders. That is, the arrangement assistant 321 may include a plurality of hollow cylinders. Also, in such cases, the quantum dot layer material 323 may be arranged to fill a space between the plurality of hollow cylinders.

The hollow (i.e., the hollow interior) of the plurality of hollow cylinders may be maintained in an empty state or may be filled with the quantum dot layer material 323 as necessary. Accordingly, optical properties such as refractive index and scattering properties of the quantum dot layer may be adjusted.

In some embodiments, the hollow interior of the plurality of hollow cylinders may be filled with air. That is, the quantum dot layer material 323 may not be arranged in the hollow interior of the plurality of hollow cylinders. For this purpose, a coating layer or the like functioning as a blocking layer may be arranged at the end of the plurality of hollow cylinders such that the quantum dot layer material 323 may not flow into the hollow interior of the plurality of hollow cylinders. In other embodiments, the quantum dot layer material 323 may fill the hollow interior of the plurality of hollow cylinders. In such cases, as a liquid quantum dot layer material 323 flows in a direction toward the upper substrate 400 from a location distant from the upper substrate 400, a portion thereof may fill the space between the plurality of hollow cylinders and the other portion thereof may fill the hollow interior of the plurality of hollow cylinders.

As described above, according to some embodiments, a color filter unit including a quantum dot layer with improved uniformity and a method of manufacturing the same may be implemented. However, the scope of the disclosure is not limited to these effects.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims and their equivalents.

What is claimed is:

1. A color filter unit comprising:
an upper substrate;
a color filter layer on a lower surface of the upper substrate; and
a quantum dot layer on a lower surface of the color filter layer and comprising a quantum dot layer material and an arrangement assistant defining a space in which the quantum dot layer material is arranged.

2. The color filter unit of claim 1, wherein the arrangement assistant comprises a porous layer comprising a plurality of spaces connected to each other.

3. The color filter unit of claim 2, wherein the quantum dot layer material fills the plurality of spaces.

4. The color filter unit of claim 1, wherein the arrangement assistant comprises a plurality of spheres.

5. The color filter unit of claim 4, wherein the space defined by the arrangement assistant is a space between the plurality of spheres and the quantum dot layer material fills the space between the plurality of spheres.

6. The color filter unit of claim 5, wherein the plurality of spheres are hollow.

7. The color filter unit of claim 6, wherein at least one hollow interior of the plurality of hollow spheres is filled with air.

8. The color filter unit of claim 6, wherein the quantum dot layer material fills at least one hollow interior of the plurality of hollow spheres.

9. The color filter unit of claim 1, wherein the arrangement assistant comprises first to third linear portions respectively extending in first to third directions that are not parallel to an upper surface of the upper substrate and that cross each other.

10. The color filter unit of claim 9, wherein the space defined by the arrangement assistant is a space between the first to third linear portions and the quantum dot layer material fills the space between the first to third linear portions.

11. The color filter unit of claim 1, wherein the arrangement assistant comprises a plurality of cylinders spaced apart from each other.

12. The color filter unit of claim 11, wherein the space defined by the arrangement assistant is a space between the plurality of cylinders and the quantum dot layer material fills the space between the plurality of cylinders.

13. The color filter unit of claim 11, wherein the plurality of cylinders are hollow cylinders.

14. The color filter unit of claim 13, wherein at least one hollow interior of the hollow cylinders is filled with air.

15. The color filter unit of claim 13, wherein the quantum dot layer material fills at least one hollow interior of the hollow cylinders.

16. The color filter unit of claim 1, wherein the arrangement assistant comprises a material differing in refractive index than the quantum dot layer material.

17. A method of manufacturing a color filter unit,
the color filter unit being on an upper substrate, the color filter unit comprising:
a color filter layer; and
a quantum dot layer,
the method comprising:
forming the color filter layer on a lower surface of the upper substrate; and
forming, on a lower surface of the color filter layer, the quantum dot layer comprising a quantum dot layer material and an arrangement assistant defining a space in which the quantum dot layer material is arranged,
wherein the forming of the quantum dot layer comprises:
forming the arrangement assistant on the lower surface of the color filter layer;
injecting the quantum dot layer material into an area where the arrangement assistant is arranged; and
curing the quantum dot layer material.

18. The method of claim 17, wherein the arrangement assistant comprises a porous layer comprising a plurality of spaces connected to each other.

19. The method of claim 17, wherein the arrangement assistant comprises a plurality of spheres.

20. The method of claim 17, wherein the arrangement assistant comprises first to third linear portions respectively extending in first to third directions that are not parallel to an upper surface of the upper substrate and that cross each other.
